(19) United States
(12) Patent Application Publication
(10) Pub. No.: US 2023/0208179 A1
(43) Pub. Date: Jun. 29, 2023

(54) BATTERY CHARGER

(71) Applicant: MAKITA CORPORATION, Anjo-shi (JP)

(72) Inventors: Masaya MIZUTANI, Anjo-shi (JP); Hisakazu OKABAYASHI, Anjo-shi (JP)

(73) Assignee: MAKITA CORPORATION, Anjo-shi (JP)

(21) Appl. No.: 18/086,080

(22) Filed: Dec. 21, 2022

(30) Foreign Application Priority Data
Dec. 28, 2021 (JP) 2021-215084

(51) Int. Cl. H02J 7/00; G01R 31/388

(52) U.S. Cl. CPC H02J 7/00718; G01R 31/388; H02J 7/0031; H02J 7/00036

(57) ABSTRACT

A battery charger in one aspect of the present disclosure includes a terminal, a power-supply circuit, a charge current path, a measurement circuit, and a control circuit. The measurement circuit includes a voltage generator and an amplifier circuit. The voltage generator (i) is provided on the charge current path and (ii) generates one or more voltages with the charge current. The amplifier circuit amplifies the one or more voltages to thereby output at least a first amplified voltage and a second amplified voltage. The control circuit cyclically obtains at least the first and second amplified voltages. The control circuit detects that the measurement circuit is in a fault condition based on at least the first and second amplified voltages obtained.

### CROSS-REFERENCE TO RELATED APPLICATIONS

The present application claims the benefit of Japanese Patent Application No. 2021-215084 filed on Dec. 28, 2021 with the Japan Patent Office, the entire disclosure of which is incorporated herein by reference.

The present disclosure relates to a battery charger to determine a fault in a current detection system.

### BACKGROUND

Japanese Patent Publication No. 6207127 discloses a battery charger including a current detection circuit on a charge current path and a microcomputer to control charging of the battery. The microcomputer controls a charge current to the battery based on a value of the charge current detected by the current detection circuit.

### SUMMARY

The above battery charger cannot properly control charging of the battery when the current detection circuit is in a fault condition and cannot accurately detect the value of the charge current.

To solve such a problem, it is considered that the microcomputer determines a fault in the current detection circuit based on the value of the charge current detected (detected value of the charge current). However, the microcomputer can determine the fault in the current detection circuit only when the detected value of the charge current is zero or an abnormal value. That is, the microcomputer cannot determine the fault in the current detection circuit when the detected value of the charge current is within a proper range.

It is desirable that one aspect of the present disclosure can more accurately detect that a measurement circuit to measure a value of a charge current to a battery is in a fault condition.

One aspect of the present disclosure provides a battery charger. The battery charger includes a terminal, a power-supply circuit, a charge current path, a measurement circuit, and a control circuit. The terminal is electrically connected to the battery. The power-supply circuit generates a charge current. The charge current path delivers (or supplies) the charge current between the power-supply circuit and the terminal. The measurement circuit includes a voltage generator and an amplifier circuit. The voltage generator (i) is on the charge current path and (ii) receives the charge current to thereby generate one or more voltages. The one or more voltages correspond to a magnitude of the charge current flowing through the charge current path.

The amplifier circuit amplifies the one or more voltages to thereby output at least a first amplified voltage and a second amplified voltage.

The control circuit cyclically obtains at least the first and second amplified voltages. The control circuit detects that the measurement circuit is in a fault condition based on at least the first and second amplified voltages obtained.

In the aforementioned battery charger, the amplifier circuit outputs at least two voltages including the first and second amplified voltages. The control circuit detects that the measurement circuit is in the fault condition based on the at least two voltages output. Accordingly, the battery charger in the present disclosure can detect that the measurement circuit is in the fault condition with satisfactory accuracy.

Another aspect of the present disclosure provides a method for detecting a measurement circuit of a battery charger being in a fault condition including:
generating one or more voltages in the measurement circuit based on a magnitude of a charge current, the measurement circuit including an amplifier circuit;
amplifying the one or more voltages with the amplifier circuit to thereby generate at least a first amplified voltage and a second amplified voltage; and
detecting the measurement circuit being in the fault condition based on at least the first and second amplified voltages.

The method above exhibits the same effects as in the charger described above.

### BRIEF DESCRIPTION OF THE DRAWINGS

Embodiments of the present disclosure will be described hereinafter by way of example with reference to the accompanying drawings, in which:

FIG. 1 is a perspective view illustrating appearances of a battery pack and a battery charger according to an embodiment;

FIG. 2 is a block diagram showing electrical configurations of the battery pack and the battery charger according to the embodiment;

FIG. 3 is a flow chart showing a charge control process executed by a second micro-processing unit (MPU) of the battery charger according to the embodiment;

FIG. 4 is a flow chart showing a fault detection process of the measurement circuit executed by the second MPU of the battery charger according to the embodiment;

FIG. 5 is a block diagram showing an electrical configuration of a battery charger according to a modified embodiment; and

FIG. 6 is a flow chart showing a fault detection process of a measurement circuit executed by a second MPU of a battery charger according to the modified embodiment.

### DETAILED DESCRIPTION OF EXEMPLARY EMBODIMENTS

### Overview of Embodiment

There is provided a battery charger according to one embodiment. The battery charger may include a terminal, a power-supply circuit, a charge current path, a measurement circuit, and/or a control circuit. The terminal may be electrically connected to the battery. The power-supply circuit may generate a charge current. The charge current path may deliver (or supply) the charge current between the power-supply circuit and the terminal. The measurement circuit may include a voltage generator and/or an amplifier circuit. The voltage generator may (i) be on the charge current path and (ii) receive the charge current to thereby generate one or more voltages. The one or more voltages may correspond to a magnitude of the charge current flowing through the charge current path. The amplifier circuit may amplify the one or more voltages to thereby output at least a first amplified voltage and a second amplified voltage. The control circuit may cyclically obtain at least the first and second amplified voltages. The control circuit may detect that the measurement circuit is in a fault condition based on at least the first and second amplified voltages obtained.

In one embodiment, the voltage generator may include a single shunt resistor. The single shunt resistor may (i) have a first end and a second end and (ii) be on the charge current path so as to receive the charge current. The one or more voltages may include a voltage between the first and second ends.

In the aforementioned battery charger, the amplifier circuit can output the first and second amplified voltages based on a first voltage generated by the single shunt resistor.

In one embodiment, the voltage generator may include a first shunt resistor and a second shunt resistor. The first shunt resistor may (i) have a first end and a second end and (ii) be on the charge current path so as to receive the charge current. The second shunt resistor may (i) have a third end and a fourth end and (ii) be connected to the first shunt resistor in series so as to receive the charge current. The one or more voltages may include (i) a first voltage between the first and second ends of the first shunt resistor and (ii) a second voltage between the third and fourth ends of the second shunt resistor. The amplifier circuit may (i) amplify the first voltage to thereby generate and output the first amplified voltage and (ii) amplify the second voltage to thereby generate and output the second amplified voltage.

In the aforementioned battery charger, the amplifier circuit can output the first amplified voltage based on the first voltage generated by the first shunt resistor. Furthermore, the amplifier circuit can output the second amplified voltage based on a second voltage generated by the second shunt resistor.

In one embodiment, the amplifier circuit may include a first amplifier and a second amplifier. The first amplifier may amplify the first voltage to thereby generate and output the first amplified voltage. The second amplifier may be an electronic component independent (or separated) from the first amplifier. The second amplifier may amplify the second voltage to thereby generate and output the second amplified voltage.

The amplifier circuit including the first and second amplifiers independent from each other can decrease the frequency of simultaneous failure (e.g., faulty state, defect, fault, improper state, abnormal state, or malfunction) of both the first and second amplifiers. That is, the aforementioned battery charger can decrease the frequency where both the first and second amplified voltages are faulty. Accordingly, when the measurement circuit is detected as being in the fault condition, this battery charger makes it easy to deal with a fault in the measurement circuit.

In one embodiment, the control circuit may detect that the measurement circuit is in the fault condition based on the first amplified voltage being out of a preset first permissible range and/or the second amplified voltage being out of a preset second permissible range.

In the aforementioned battery charger, the control circuit can accurately and stably detect that the measurement circuit is in the fault condition.

In one embodiment, the control circuit may calculate a first difference between the first amplified voltage and a desired voltage. The desired voltage may correspond to a desired value of the charge current. The control circuit may calculate a second difference between the second amplified voltage and the desired voltage. The control circuit may detect that the measurement circuit is in the fault condition based on the first difference being out of a preset third permissible range and/or the second difference being out of a preset fourth permissible range.

In the aforementioned battery charger, the control circuit can accurately and stably detect that the measurement circuit is in the fault condition.

In one embodiment, the control circuit may calculate a third difference between the first and second amplified voltages. The control circuit may detect that the measurement circuit is in the fault condition based on the third difference being out of a preset fifth permissible range.

In the aforementioned battery charger, the control circuit can accurately and stably detect that the measurement circuit is in the fault condition.

In one embodiment, the control circuit may, during the battery charger charging the battery, control the power-supply circuit to stop supply of the charge current therefrom based on the control circuit detecting that the measurement circuit is in the fault condition.

In the aforementioned battery charger, when the measurement circuit is detected as being in the fault condition, the control circuit can stop charging of the battery to thereby suppress deterioration of the battery resulting from overcharging or the like.

In one embodiment, the amplifier circuit may include a first amplifier and a second amplifier. The one or more voltages may include a first voltage. The first amplifier may amplify the first voltage at a first accuracy. The second amplifier may amplify the first voltage at a second accuracy. The second accuracy may be distinctive from the first accuracy.

In the aforementioned battery charger, one of the first or second amplifier can have an accuracy lower than an accuracy of the other. This can reduce the cost of the amplifier circuit.

In one embodiment, the amplifier circuit may include a first amplifier and a second amplifier. The one or more voltages may include a first voltage and a second voltage distinctive from the first voltage. The first amplifier may amplify the first voltage at a first accuracy. The second amplifier may amplify the second voltage at a second accuracy. The second accuracy may be distinctive from the first accuracy.

In the aforementioned battery charger, one of the first or second amplifier can have an accuracy lower than an accuracy of the other. This can reduce the cost of the amplifier circuit. Furthermore, in the aforementioned battery charger, the amplifier circuit can output two independent amplified voltages having accuracies distinctive from each other.

In one embodiment, the battery charger may further include a feedback circuit connected to the first amplifier and to the power-supply circuit. The first accuracy may be higher than the second accuracy. The first amplifier may input the first amplified voltage to the feedback circuit. The feedback circuit may control the power-supply circuit so as to maintain the first amplified voltage at a desired voltage. The desired voltage corresponds to a desired value of the charge current.

The aforementioned battery charger performs a feedback control of the charge current based on the first amplified voltage having the accuracy higher than the accuracy of the second amplified voltage. Accordingly, the aforementioned battery charger can control the charge current with satisfactory accuracy.

In the aforementioned battery charger, the second accuracy is lower than the first accuracy. This can reduce the cost of the second amplifier with respect to the cost of the first amplifier. Accordingly, the cost of the battery charger can be reduced as compared to a case where the second accuracy is the same as the first accuracy.

In one embodiment, the first amplifier may include a first differential amplifier having a first offset voltage. The second amplifier may include a second differential amplifier having a second offset voltage. The first offset voltage may be lower than the second offset voltage.

In the aforementioned battery charger, when the first offset voltage is lower than the second offset voltage, the first accuracy can be higher than the second accuracy.

There may be provided a method for detecting a measurement circuit of a battery charger being in a fault condition according to one embodiment. The method may include:
generating one or more voltages in the measurement circuit based on a magnitude of a charge current, the measurement circuit including an amplifier circuit;
amplifying the one or more voltages with the amplifier circuit to thereby generate at least a first amplified voltage and a second amplified voltage; and
detecting the measurement circuit being in the fault condition based on at least the first and second amplified voltages.

Executing the method above exhibits the same effects as in the battery charger mentioned above.

In one embodiment, the features above may be combined in any manner. Furthermore, in one embodiment, at least one of the features above may be omitted (or eliminated).

### Specific Example Embodiment

### 1. Configuration

### 1-1. Overall Configuration of Charging System

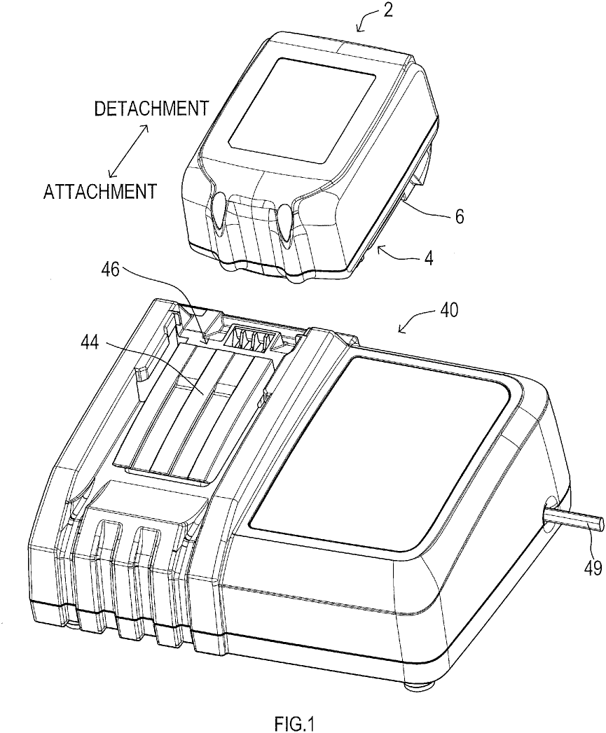

Reference is made to FIG. 1 to describe an overall configuration of a charging system according to the present embodiment. The charging system according to the present embodiment includes a battery pack 2 and a battery charger 40.

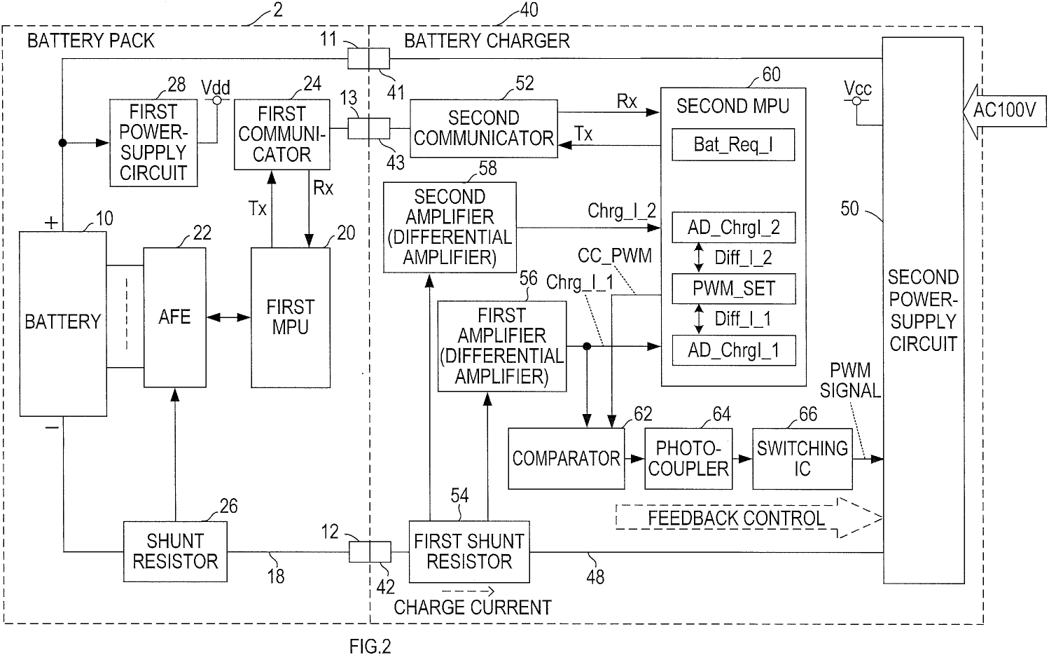

The battery pack 2 houses therein a battery 10 (see, FIG. 2). The battery pack 2 includes a first attachment portion 4. The first attachment portion 4 is coupled to the battery charger 40 and/or an electric work machine. Examples of the electric work machine include a rechargeable electric power tool, a rechargeable cleaner, and a rechargeable mower. The first attachment portion 4 includes a first terminal portion 6. Upon the electric work machine being attached to the first attachment portion 4, the battery pack 2 is electrically connected to the electric work machine via the terminal portion 6, and then delivers (or supplies) an electric power of battery 10 to the electric work machine.

The battery charger 40 includes a power cord 49. The battery charger 40 is supplied with an electric power from an external power supply (for example, a commercial power source or a utility power for an alternating current (AC) voltage) via the power cord 49 to thereby generate a charge voltage (for example, direct current (DC) voltage) for charging the battery 10.

The battery charger 40 includes a second attachment portion 44. The second attachment portion 44 has a shape to correspond (or fit) to the shape of the first attachment portion 4 of the battery pack 2 so as to slidably receive the battery pack 2. The second attachment portion 44 includes a second terminal portion 46. The second terminal portion 46 is fitted to the first terminal portion 6. As the first attachment portion 4 is attached to the second attachment portion 44, the first terminal portion 6 is fitted to the second terminal portion 46. Then, the battery charger 40 is electrically connected to the battery pack 2 via the second terminal portion 46 and the first terminal portion 6.

Upon the battery charger 40 being electrically connected to the battery pack 2, the battery charger 40 delivers the charge current to the battery pack 2 via the second terminal portion 46.

As shown in FIG. 2, the first terminal portion 6 includes a first positive terminal 11, a first negative terminal 12, and a first communication terminal 13. The second terminal portion 46 includes a second positive terminal 41, a second negative terminal 42, and a second communication terminal 43.

The first positive terminal 11 is connected to the positive electrode of the battery 10. The first negative terminal 12 is connected to the negative electrode of the battery 10. The first communication terminal 13 is connected to a first communicator 24, which will be described later. The battery pack 2 communicates with the battery charger 40 or the electric work machine via the first communication terminal 13.

When the first attachment portion 4 is attached to the second attachment portion 44, the second positive terminal 41 is connected to the first positive terminal 11, and the second negative terminal 42 is connected to the first negative terminal 12. The second communication terminal 43 is connected to the first communication terminal 13. The second communication terminal 43 is connected to a second communicator 52, which will be described later. The battery charger 40 communicates with the battery pack 2 via the second communication terminal 43.

### 1-2. Electrical Configuration of Charging System

Reference is made to FIG. 2 to describe an electrical configuration of a charging system. The battery pack 2 includes a battery 10. The battery 10 includes two or more cells that can be charged and discharged. The two or more cells are coupled in series.

The battery pack 2 includes a first micro-processing unit (first MPU) 20, an analog front end (AFE) 22, a first communicator 24, a shunt resistor 26, and a first power-supply circuit 28. In another embodiment, at least one of the first MPU 20, the AFE 22, the first communicator 24, the shunt resistor 26, or the first power-supply circuit 28 may be eliminated (or omitted) from the battery pack 2.

The first MPU 20 includes a Central Processing Unit (CPU), a Read-Only Memory (ROM), and a Random-Access Memory (RAM). The AFE 22 performs data communication with the first MPU 20 to thereby input various detection signals to the first MPU 20.

For example, the AFE 22 obtains a battery voltage or a voltage of each cell (cell voltage) from the battery 10 to thereby input the same to the first MPU 20. Furthermore, the AFE 22 obtains a battery temperature from a temperature sensor provided to the battery 10 to thereby input the same to the first MPU 20.

The first communicator 21 performs serial communication via the first communication terminal 13 based on a command from the first MPU 20.

The shunt resistor 26 is on a charge and discharge current path 18 that connects the negative electrode of the battery 10 to the first negative terminal 12. The shunt resistor 26 has a first end and a second end. Between the first and second ends of the shunt resistor 26, the shunt resistor 26 generates a voltage in accordance with a magnitude of a discharge current flowing through the charge and discharge current path 18. Based on the voltage between the first and second ends of the shunt resistor 26, the AFE 22 measures a value of the discharge current from the battery 10 to the electric work machine. The AFE 22 inputs the value of the discharge current measured (measured value of the discharge current) to the first MPU 20.

With the electric power from the battery 10, the first power-supply circuit 28 generates a power-supply voltage (direct-current constant voltage) Vdd so as to drive the first MPU 20, the AFE 22, the first communicator 24, and the like, and delivers the power-supply voltage generated to each of these mentioned above.

The first MPU 20 achieves various functions by the CPU executing a program stored in the ROM. For example, the first MPU 20 executes a process to detect a fault condition during charging and/or discharging of the battery 10 based on various values input from the AFE 22, such as a value of the battery voltage, a value of the cell voltage, the battery temperature, and the value of the discharge current.

When detecting the faulty condition, the first MPU 20 transmits a command to the battery charger 40 via the first communicator 24 so as to control the battery charger 40 to stop charging the battery 10. Alternatively, when detecting the fault condition, the first MPU 20 transmits a command to the electric work machine via the first communicator 24 so as to control the electric work machine to stop discharging the battery 10.

The first MPU 20 monitors an accumulated electric energy based on the value of the discharge current measured via the shunt resistor 26 and/or the value of the charge current measured by the battery charger 40. The accumulated electric energy is an electric energy accumulated in the battery 10.

During the charging of the battery 10 by the battery charger 40, the first MPU 20 sets the value (setting value) of the charge current based on the accumulated electric energy to be successively updated. Then, the first MPU 20 designates (or commands) the setting value of a charge current to the battery charger 40. During discharging to the electric work machine, the first MPU 20 determines whether the accumulated electric energy decreases to a stop determination value based on the accumulated electric energy successively updated. When the accumulated electric energy decreases to the stop determination value, the first MPU 20 controls the battery 20 to stop discharging to the electric work machine.

The battery charger 40 includes a second power-supply circuit 50, a second communicator 52, a first shunt resistor 54, a first amplifier 56, a second amplifier 58, a second MPU 60, a comparator 62, a photocoupler (or an optocoupler or an opto-isolator) 64, and a switching integrated circuit (hereinafter, referred to as “switching IC”). In another embodiment, at least one of the second power-supply circuit 50, the second communicator 52, the first shunt resistor 54, the first amplifier 56, the second amplifier 58, the second MPU 60, the comparator 62, the photocoupler 64, or the switching IC may be eliminated (or omitted) from the battery charger 40.

The second power-supply circuit 50 generates the charge current to the battery 10 by converting an alternating voltage (for example, AC 100 V) to be delivered from the external power supply via the power cord 49 into a direct voltage for charging the battery 10.

The second power-supply circuit 50 incudes a positive electrode connected to the second positive terminal 41 via a charge current path 48. The second power-supply circuit 50 includes a negative electrode connected to the second negative terminal 42 via the charge current path 48.

In addition to the charge voltage to the battery 10, the second power-supply circuit 50 generates a power-supply voltage Vcc so as to drive an internal circuit of the battery charger 40, that is, the second communicator 52, the first amplifier 56, the second amplifier 58, the second MPU 60, the comparator 62, and the like.

The second MPU 60 includes a CPU, a ROM, a RAM, and an analog-to-digital (A/D) convertor. The second MPU 60 achieves various functions by the CPU executing various programs stored in the ROM.

The second communicator 52 is connected to the second communication terminal 43. The second communicator 52 performs serial communication via the second communication terminal 43 based on a command from the second MPU 60.

The first shunt resistor 54 is an electronic component corresponding to one example of the voltage generator in the present disclosure. The first shunt resistor 54 is on a negative side of the charge current path 48 between the second negative terminal 42 and the second power-supply circuit 50. The first shunt resistor 54 has a first end and a second end. The first shunt resistor 54 receives the charge current to thereby generate a first voltage. The first voltage corresponds to a voltage between the first and second ends, and corresponds to a magnitude of the charge current flowing through the charge current path 48. The second MPU 60 obtains the value of the charge current based on the value of the first voltage.

Since the first shunt resistor 54 is an electronic component consisting of a single resistor, there is no need to trim the resistor by laser trimming or the like. This means that a resistance value of the first shut resistor 54 does not change due to trimming. Furthermore, the first shunt resistor 54 having no trimmed part does not undergo a short-circuit fault of the trimmed part due to the charge current flowing therethrough.

The shunt resistor 26 of the battery pack 2 carries, in addition to the charge current, the discharge current greater than the charge current. The shunt resistor 26 is an electronic component consisting of a single resistor, and has a rated power greater than the first shunt resistor 54 does.

The first and second amplifiers 56, 58 amplify the first voltage to a voltage that can be input to the second MPU 60. Specifically, the first amplifier 56 amplifies the first voltage input therein at a first accuracy. Then, the first amplifier 56 outputs, to the second MPU 60, a first measurement signal Chrg_I_1 indicating the first amplified voltage. The first amplified voltage corresponds to the first voltage amplified by the first amplifier 56. The second amplifier 58 amplifies the first voltage input therein at a second accuracy. Then, the second amplifier 58 outputs, to the second MPU 60, a second measurement signal Chrg_I_2 indicating the second amplified voltage. The second amplified voltage corresponds to the first voltage amplified by the second amplifier 58. The first and second amplified voltages correspond to the charge current.

The second amplifier 58 is an electronic component independent from the first amplifier 56. The first amplifier 56 is a differential amplifier including a first operational amplifier. The second amplifier 58 is a differential amplifier including a second operational amplifier. The first operational amplifier has an offset voltage different from an offset voltage across the second operational amplifier. Specifically, the offset voltage across the first operational amplifier is lower than the offset voltage across the second operational amplifier. Accordingly, the first accuracy is higher than the second accuracy. That is, the first amplifier 56 has a current measurement accuracy higher than a current measurement accuracy of the second amplifier 58. In the present embodiment, the first and second amplifiers 56, 58 correspond to one example of the amplifier circuit in the present disclosure.

The second MPU 60 includes an analog-to-digital (A/D) converter (not shown) to execute an analog-to-digital (A/D) conversion of each of the first and second measurement signals Chrg_I_1, Chrg_I_2 to thereby obtain a first measurement value AD_Chrg_I_1 and a second measurement value AD_Chrg_I_2.

The second MPU 60 detects that a measurement circuit is in a fault condition based on the first and second measurement values AD_Chrg_I_1, AD_Chrg_I_2. The measurement circuit includes the first shunt resistor 54, and the first and second amplifiers 56, 58. Furthermore, the measurement circuit may include the A/D converter of the second MPU 60. In another embodiment, at least one of the first shunt resistor 54, the first amplifier 56, or the second amplifier 58 may be eliminated from the measurement circuit.

In the present embodiment, the second MPU 60 calculates a first difference Diff_I_1 and a second difference Diff_I_2. The first difference Diff_I_1 is a difference between the first measurement value AD_Chrg_I_1 and a desired value PWM_SET of the charge current. That is, the first difference Diff_I_1 corresponds to a difference between the first amplified voltage and a desired voltage. The desired voltage corresponds to the desired value PWM_SET of the charge current. The second difference Diff_I_2 is a difference between the second measurement value AD_Chrg_I_2 and the desired value PWM_SET of the charge current. That is, the second difference Diff_I_2 corresponds to a difference between the second amplified voltage and the desired voltage. The second MPU 60 detects that the measurement circuit is in the fault condition based on the first and second differences Diff_I_1, Diff_I_2 calculated.

The second MPU 60 sets the desired value PWM_SET of the charge current in accordance with a value of the charge current (hereinafter, referred to as “designated value”) Bat_Req_I designated by the first MPU 20 of the battery pack 2. The second MPU 60 executes a digital-to-analog (D/A) conversion of the desired value PWM_SET to thereby generate a desired current signal CC_PWM and output the same to the comparator 62.

The comparator 62 compares the desired current signal CC_PWM input from the second MPU 60 with the first measurement signal Chrg_I_1 to thereby generate a differential signal. The comparator 62 outputs the differential signal to the switching IC 66 via the photocoupler 64. The differential signal indicates a difference between an actual charge current and a desired current.

The switching IC 66 is a switching circuit to control the charge current to be generated by the second power-supply circuit 50. The switching IC 66 generates a pulse-width modulation (PWM) signal to control the second power-supply circuit 50 so as to maintain the first measurement signal Chrg_I_1 at the desired current signal CC_PWM, that is, to set the differential signal to zero (0). In other words, the switching IC 66 generates the PWM signal so as to maintain the first amplified voltage at the desired voltage. The switching IC 66 outputs the PWM signal generated to the second power-supply circuit 50.

The second power-supply circuit 50 generates the charge current based on the PWM signal input thereto. In the present embodiment, the comparator 62, the photocoupler 64, and the switching IC 66 correspond to one example of the feedback circuit in the present disclosure.

### 2. Process

### 2-1. Charge Control Process

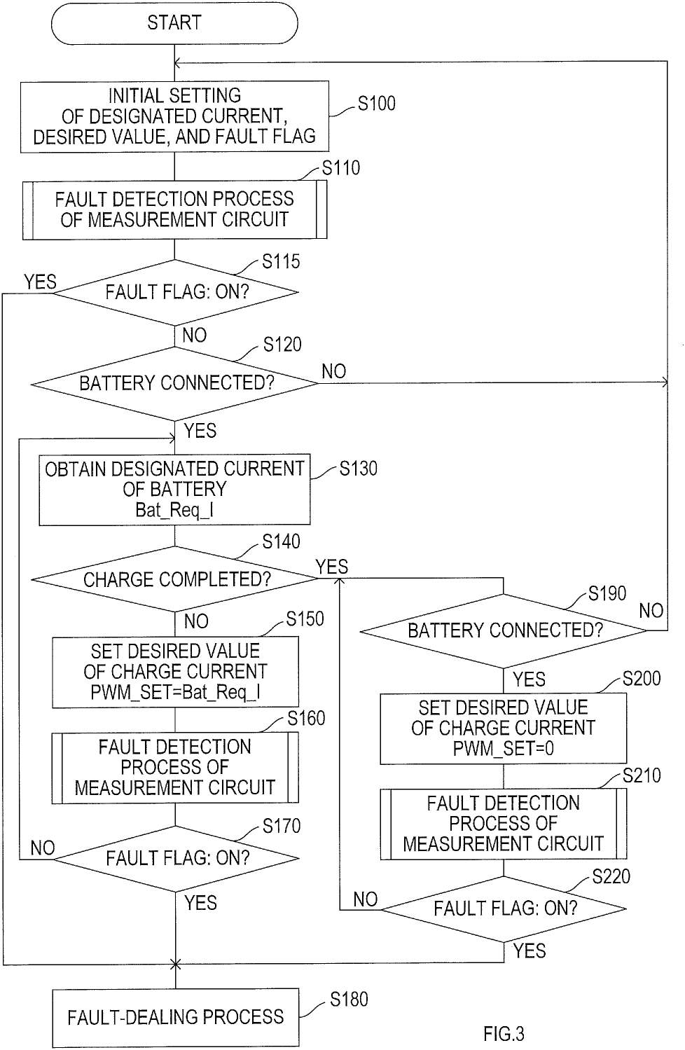

Reference is made to FIG. 3 to describe a charge control process to be executed by the second MPU 60 of the battery charger 40. The second MPU 60 achieves the charge control process by the CPU executing the program stored in advance in the ROM or the like.

In S100, the second MPU 60 executes an initial setting process. Specifically, the second MPU 60 sets initial values of the designated value Bat_Req_I and the desired value PWM_SET of the charge current to zero (0) and turn off a fault flag.

Subsequently, in S110, the second MPU 60 executes a fault detection process of the measurement circuit. Specifically, the second MPU 60 determines whether the value of the charge current measured by the first and second amplifiers 56, 58 is proper. If determining that the value of the charge current is faulty, then the second MPU 60 turns on the fault flag to indicate that the measurement circuit is in the fault condition. Details of the process to detect the fault condition will be described later. Upon executing a process of S100, the second MPU 60 proceeds to a process of S115.

In S115, the second MPU 60 determines whether the fault flag has been turned on. If the fault flag has been turned off, that is, the measurement circuit has been in a proper condition (S115: NO), then the second MPU 60 proceeds to a process of S120.

If the fault flag has been turned on, that is, the measurement circuit has been in the fault condition (S115: YES), then the second MPU 60 proceeds to a process of S180.

In S180, the second MPU 60 executes a fault-dealing process. Specifically, the second MPU 60 notifies, via a not-shown notifier, that the measurement circuit has been in the fault condition. The notifier is, for example, a light-emitting diode (LED) for displaying the fault condition. The second MPU 60 turns on or off the LED to thereby notify that the measurement circuit has been in the fault condition.

Furthermore, the second MPU 60 executes the fault-dealing process to thereby control the second power-supply circuit 50 to stop outputting the charge current therefrom. For example, the second MPU 60 may set the desired value PWM_SET of the charge current to zero (0). Alternatively, the second MPU 60 may turn off a switch provided to the charge current path 48 to thereby interrupt the charge current path 48.

In S120, the second MPU 60 determines whether the battery 10 is connected to the battery charger 40. Specifically, the second MPU 60 determines that the battery 10 is connected to the battery charger 40 when being able to communicate with the battery pack 2 via the second communicator 52. The second MPU 60 determines that the battery 10 is not connected to the battery charger 40 when not being able to communicate with the battery pack 2. If determining that the battery 10 is not connected to the battery charger 40 (S120: NO), then the second MPU 60 returns to a process of S100. If determining that the battery 10 is connected to the battery charger 40 (S120: YES), then the second MPU 60 proceeds to a process of S130.

In S130, the second MPU 60 communicates with the battery pack 2 via the second communicator 52 to thereby obtain the designated value Bat_Req_I from the battery pack 2.

In S140, the second MPU 60 determines whether the charging of the battery 10 has completed. The second MPU 60 determines that the charging of the battery 10 has completed when, for example, the designated value Bat_Req_I from the battery pack 2 is zero (0), or equal to or less than a charge complete threshold.

If determining that the charging of the battery 10 has not completed (S140: NO), then the second MPU 60 proceeds to a process of S150.

In S150, the second MPU 60 sets the desired value PWM_SET of the charge current based on the designated value Bat_Req_I obtained from the battery pack 2 in S130.

The desired value PWM_SET is converted from a digital to an analog form into a signal indicating a desired current CC_PWM. The signal indicating the desired current CC_PWM is output to the comparator 62. As a result, the feedback circuit including the comparator 62, the photocoupler 64, and the power switching IC 66 maintains the charge current to the battery 10 at the desired current CC_PWM.

Subsequently, in S160, the second MPU 60 executes the fault detection process of the measurement circuit as in the process of S110, and proceeds to a process of S170.

In S170, the second MPU 60 determines whether the fault flag has been turned on as in the process of S115.

If determining that the fault flag has been turned off (S170: NO), then the second MPU 60 returns to the process of S130. If determining that the fault flag has been turned on (S170: YES), then the second MPU 60 proceeds to a process of S180 to execute the fault-dealing process.

If determining that the charging of the battery 10 has completed in S140 (S140: YES), then the second MPU 60 proceeds to a process of S190.

In S190, the second MPU 60 determines whether the battery 10 is connected to the battery charger 40 as in the process of S120. If determining that the battery 10 is not connected to the battery charger 40 (S190: NO), then the second MPU 60 returns to the process of S100. If determining that the battery 10 is connected to the battery charger 40 (S190: YES), then the second MPU 60 proceeds to a process of S200.

In S200, the second MPU 60 sets the desired value PWM_SET of the charge current to zero (0) to thereby control the second power-supply circuit 50 to stop outputting the charge current therefrom.

In S210, the second MPU 60 executes the fault detection process of the measurement circuit as in the process of S160, and proceeds to a process of S220.

In S220, the second MPU 60 determines whether the fault flag has been turned on as in processes of S115 and S170. If determining that the fault flag has been turned off (S220: NO), then the second MPU 60 returns to the process of S190. If determining that the fault flag has been turned on (S220: YES), then the second MPU 60 proceeds to the process of S180 to execute the fault-dealing process.

### 2-2. Fault Detection Process of Control Circuit

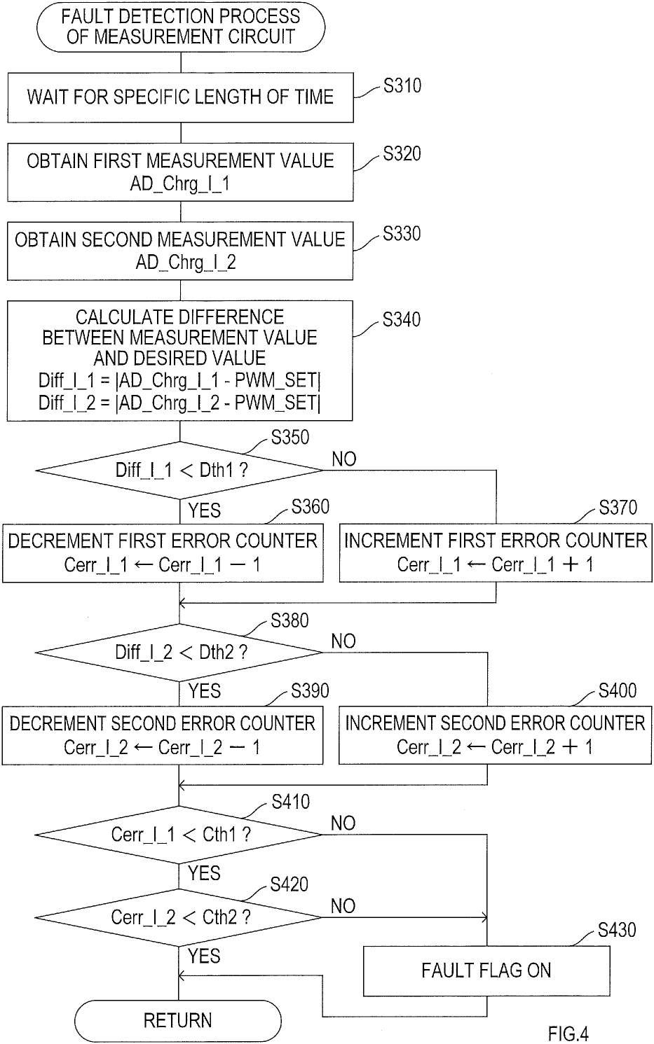

Reference is made to FIG. 4 to describe the fault detection process of the measurement circuit executed by the second MPU 60 in S110, S160, or S210.

In S310, the second MPU 60 waits until elapse of a specific length of time (for example, 125 milliseconds (ms)) since the previous fault detection process of the measurement circuit has started. If the specific length of time has elapsed, then the second MPU 60 proceeds to a process of S320.

In S320, the second MPU 60 obtains the first measurement value AD_Chrg_I_1 based on the first measurement signal Chrg_I_1 input from the first amplifier 56.

In S330, the second MPU 60 obtains the second measurement value AD_Chrg_I_2 based on the second measurement signal Chrg_I_2 input from the second amplifier 58.

In S340, the second MPU 60 calculates the first and second differences Diff_I_1, Diff_I_2. The first difference Diff_I_1 is a magnitude of the difference between the first measurement value AD_Chrg_I_1 obtained in S320 and the desired value PWM_SET of the charge current (that is, an absolute value of the difference). The second difference Diff_I_2 is a magnitude of the difference between the second measurement value AD_Chrg_I_2 obtained in S330 and the desired value PWM_SET of the charge current.

Subsequently, in S350, the second MPU 60 determines whether the first difference Diff_I_1 calculated in S340 is smaller than a first threshold value Dth1 (for example, “100”). The first threshold value Dth1 is a preset threshold value to determine a fault. If determining that the first difference Diff_I_1 is smaller than the first threshold value Dth1 (S350: YES), then the second MPU 60 proceeds to a process of S360.

In S360, the second MPU 60 identifies that the first measurement value AD_Chrg_I_1 is proper, and then decrements a value of a first error counter Cerr_I_1 by “one” (-1). Subsequent to the process of S360, the second MPU 60 proceeds to a process of S380.

If determining that the first difference Diff_I_1 is greater than or equal to the first threshold value Dth1 (S350: NO), then the second MPU 60 proceeds to a process of S370.

In S370, the second MPU 60 identifies that the first measurement value AD_Chrg_I_1 is faulty, and then increments the value of the first error counter Cerr_I_1 by “one” (+1). Subsequent to the process of S370, the second MPU 60 proceeds to a process of S380.

The second MPU 60 determines whether the second difference Diff_I_2 calculated in S340 is smaller than a second threshold value Dth2 (for example, “250”). The second threshold value Dth2 is a preset threshold value to determine the fault. The first measurement value AD_Chrg_I_1 achieves a measurement accuracy (hereinafter, referred to as “first measurement accuracy”) higher than a measurement accuracy (hereinafter, referred to as “second measurement accuracy”) of the second measurement value AD_Chrg_I_2. Thus, the second threshold value Dth2 is set to a value greater than the first threshold value Dth1 (Dth1<Dth2).

Setting the first threshold value Dth1 to a value smaller than the second threshold value Dth2 limits a permissible range (hereinafter, referred to as “first permissible range”) of the first measurement value AD_Chrg_I_1 to be narrower than a permissible range (hereinafter, referred to as “second permissible range”) of the second measurement value AD_Chrg_I_2. Even in this case, the first measurement accuracy, which is higher than the second measurement, allows accurate detection of the fault in the first measurement value AD_Chrg_I_1.

If determining that the second difference Diff_I_2 is smaller than the second threshold value Dth2 (S380: YES), then the second MPU 60 proceeds to a process of S390.

In S390, the second MPU 60 identifies that the second measurement value AD_Chrg_I_2 is proper, and then decrements a value of a second error counter Cerr_I_2 by “one” (-1). Subsequent to the process of S390, the second MPU 60 proceeds to a process of S410.

If determining that the second difference Diff_I_2 is greater than or equal to the second threshold value Dth2 (S380: NO), then the second MPU 60 proceeds to a process of S400.

In S400, the second MPU 60 identifies that the second measurement value AD_Chrg_I_2 is faulty, and then increments the value of the second error counter Cerr_I_2 by “one” (+1). Subsequent to the process of S400, the second MPU 60 proceeds to a process of S410.

It should be noted that each of the first and second error counters Cerr_I_1, Cerr_I_2 has a minimum value of zero (0). Decrementing the value of each of the first and second error counters Cerr_I_1, Cerr_I_2 does not result in a minus value.

In S410, the second MPU 60 determines whether the value of the first error counter Cerr_I_1 is smaller than a first counter threshold Cth1 that is preset. If determining that the value of the first error counter Cerr_I_1 is smaller than the first counter threshold Cth1 (S410: YES), then the second MPU 60 proceeds to S420.

In S420, the second MPU 60 determines whether the value of the second error counter Cerr_I_2 is smaller than a second counter threshold Cth2 that is preset. If determining that the value of the second error counter Cerr_I_2 is smaller than the second counter threshold Cth2 (S420: YES), then the second MPU 60 determines that the measurement circuit is in a proper condition, and then ends the present process.

Each of the first and second counter thresholds Cth1, Cth2 is set to, for example, “32”. When the second MPU 60 executes the present process in the above-described cycle of 125 ms, the measurement circuit is detected as being in the fault condition in response to (i) the first difference Diff_I_1 being greater than or equal to the first threshold value Dth1 over a period of 4 seconds or (ii) the second difference Diff_I_2 being greater than or equal to the second threshold value Dth2 over a period of 4 seconds.

The first and second threshold values Dth1, Dth2 and the first and second counter thresholds Cth1, Cth2 can be appropriately determined in accordance with characteristics of the battery charger 40 and/or characteristics of the battery pack 2 that comprise(s) the second MPU 60.

If determining in S410 that the value of the first error counter Cerr-I-1 is greater than or equal to the first counter threshold Cth1 (S410: NO), then the second MPU 60 proceeds to a process of S430. Furthermore, if determining in S420 that the value of the second error counter Cerr_I_2 is greater than or equal to the second counter threshold Cth2 (S420: NO), then the second MPU 60 proceeds to a process of S430.

In S430, the second MPU 60 detects that the measurement circuit is in the fault condition, and then turns on the fault flag to end the present process.

The fault in the measurement circuit according to the present embodiment includes a failure of at least one of the first shunt resistor 54, the first amplifier 56, or the second amplifier 58. Alternatively, the fault in the measurement circuit according to the present embodiment includes a failure of at least one of the first shunt resistor 54, the first amplifier 56, the second amplifier 58, or the A/D converter inside the second MPU 60.

### 3. Effects

As described above, the battery charger 40 according to the present embodiment exhibits effects to be described below.

The first voltage is input to each of the first and second amplifiers 56, 58 from the first shunt resistor 54 on the charge current path 48 to the battery pack 2. The first amplifier 56 amplifies the first voltage to thereby output the first measurement signal Chrg_I_1 to the second MPU 60. The second amplifier 58 amplifies the first voltage to thereby output the second measurement signal Chrg_I_2 to the second MPU 60.

The second MPU 60 determines whether (i) the first measurement value AD_Chrg_I_1 corresponding to the first measurement signal Chrg_I_1 and (ii) the second measurement value AD_Chrg_I_2 corresponding to the second measurement signal Chrg_I_2 are within normal ranges. If determining that the first measurement value AD-Chrg-I-1and/or the second measurement value AD_Chrg_I_2 are/is out of the normal ranges, then the second MPU 60 turns on the fault flag so as to control the second power-supply circuit 50 to stop outputting the charge current therefrom.

Accordingly, the battery charger 40 can detect, with satisfactory accuracy, that the fault condition is present in the measurement circuit including the first shunt resistor 54, the first amplifier 56, and second amplifier 58. Consequently, the battery charger 40 can inhibit the charge current from being erroneously controlled to a current value different from the desired current.

(2) The charge current to the battery 10 is controlled so as to have the desired current based on the first measurement value AD_Chrg_I_1 measured at the first measurement accuracy higher than the second measurement accuracy. This can increase the control accuracy for the charge current.

(3) The second measurement accuracy is lower than the first measurement accuracy, which can reduce a cost of the second amplifier 58 with respect to a cost of the first amplifier 56. This can consequently reduce the total cost of the battery charger 40.

### Modified Embodiments

Although the embodiment of the present disclosure has been described hereinabove, the present disclosure is not limited to the above-described example embodiment and can be variously practiced.

### 1. First Modified Embodiment

In the example embodiment above, the battery charger 40 includes the first shunt resistor 54, which is a single component on the charge current path 48. Each of the first and second amplifiers 56, 58 amplifies the first voltage to be output from the first shunt resistor 54.

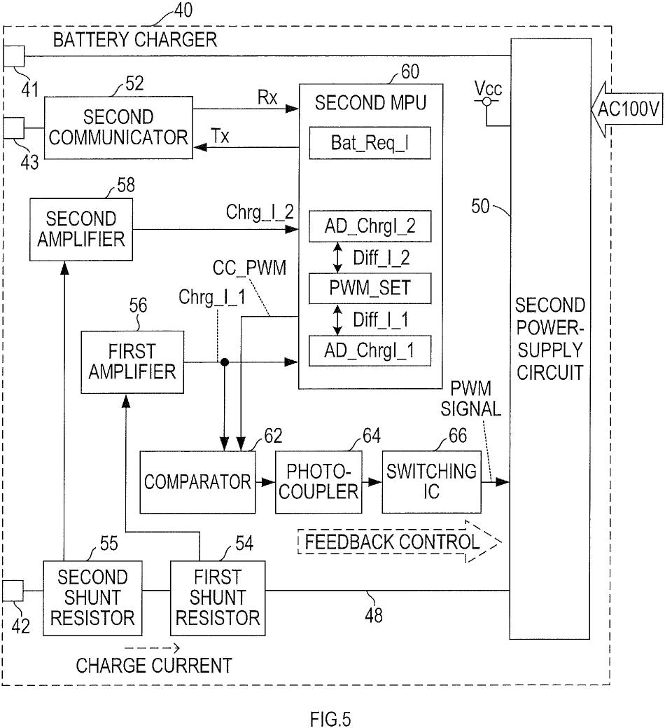

In contrast, the battery charger 40 according to a first modified embodiment includes, as shown in FIG. 5, the first shunt resistor 54 and a second shunt resistor 55 on the charge current path 48. The second shunt resistor 55 is connected to the first shunt resistor 54 in series. The first shunt resistor 54 has a first end and a second end. The first shunt resistor 54 generates a first voltage with the charge current. The first voltage corresponds to a voltage between the first and second ends. The second shunt resistor 55 has a third end and a fourth end. The second shunt resistor 55 generates a second voltage with the charge current. The second voltage corresponds to a voltage between the third and fourth ends.

The first shunt resistor 54 outputs the first voltage to the first amplifier 56. The first amplifier 56 amplifies the first voltage to thereby output the first measurement signal Chrg_I_1. The second shunt resistor 55 outputs the second voltage to the second amplifier 58. The second amplifier 58 amplifies the second voltage to thereby output the second measurement signal Chrg_I_2.

Accordingly, the first amplifier 56 has a one-to-one relation with the first shunt resistor 54. The second amplifier 58 has a one-to-one relation with the second shunt resistor 55.

The first modified embodiment exhibits effects to be described below.

The measurement circuit can be divided into a first auxiliary measurement circuit and a second auxiliary measurement circuit. The first auxiliary measurement circuit includes the first amplifier 56 and the first shunt resistor 54. The second auxiliary measurement circuit includes the second amplifier 58 and the second shunt resistor 55. The second MPU 60 can individually detect (i) the first auxiliary measurement circuit being in a fault condition and (ii) the second auxiliary measurement circuit being in a fault condition.

The first and second shunt resistors 54, 55 may be on the charge current path 48 between the second positive terminal 41 and the second power-supply circuit 50 in place of the charge current path 48 between the second negative terminal 42 and the second power-supply circuit 50.

### 2. Second Modified Embodiment

In the example embodiment above, the second MPU 60 calculates (i) an absolute value of the difference between the first measurement value AD_Chrg_I_1 and the desired value PWM_SET of the charge current as the first difference Diff_I_1 and (ii) an absolute value of the difference between the second measurement value AD_Chrg_I_2 and the desired value PWM_SET of the charge current as the second difference Diff_I_2.

In the second modified embodiment, the second MPU 60 detects that the measurement circuit is in the fault condition based on an absolute value of a difference between the first and second measurement values AD_Chrg_I_1, AD_Chrg_I_2 (hereinafter, referred to as “third difference Diff_I_3”).

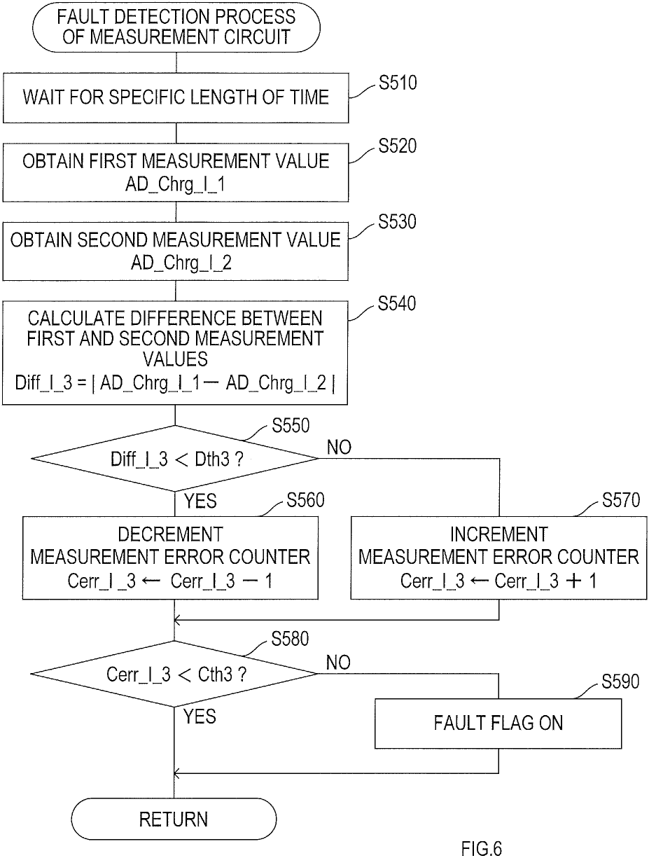

Reference is made to FIG. 6 to describe a fault detection process of the measurement circuit according to the second modified embodiment executed by the second MPU 60.

In S510 through S530, the second MPU 60 executes the same processes of S310 through S330 shown in FIG. 4.

In S540, the second MPU 60 calculates the third difference Diff_I_3. The third difference Diff_I_3 is the absolute value of the difference between the first and measurement value AD_Chrg_I_1 obtained in S520 and the second measurement value AD_Chrg_I_2 obtained in S530.

Subsequently, in S550, the second MPU 60 determines whether the third difference Diff_I_3 calculated in S540 is smaller than a third threshold value Dth3 (for example, “350”).

If determining in S550 that the third difference Diff_I_3 is smaller than the third threshold value Dth3 (S550: YES), then the second MPU 60 proceeds to a process of S560.

In S560, the second MPU 60 identifies that the first and second measurement values AD_Chrg_I_1, AD_Chrg_I_2 are proper, and then decrements a value of a measurement error counter Cerr_I_3 by “one” (-1). Subsequent to the process of S560, the second MPU 60 proceeds to a process of S580.

If determining that the third difference Diff_I_3 is greater than or equal to the third threshold Dth3 (S550: NO), then the second MPU 60 proceeds to a process of S570.

In S570, the second MPU 60 identifies that the first measurement value AD_Chrg_I_1 and/or the second measurement value AD_Chrg_I_2 are/is faulty, and the increments the value of the measurement error counter Cerr_I_3 by “one” (+1). Subsequent to the process of S570, the second MPU 60 proceeds to a process of S580.

The measurement error counter Cerr_I_3 has the same minimum value of zero (0) as those of the first and second error counters Cerr_I_1, Cerr_I_2 in the example embodiment above. Decrementing the value of the measurement error counter Cerr_I_3 does not result in a minus value.

Furthermore, the third threshold value Dth3 is greater than the first and second threshold values Dth1, Dth2 in the example embodiment above. In the second modified embodiment, the third threshold value Dth3 corresponds to a value obtained by adding the second threshold value Dth2 to the first threshold value Dth1. The third threshold value Dth3 is set to the above-described value so as to enable the second MPU 60 to determine that (i) the first measurement value AD_Chrg_I_1 is within the first permissible range and (ii) the second measurement value AD_Chrg_I_2 is within the second permissible range.

In other words, the second MPU 60 in the second modified embodiment can determine that the first measurement value AD_Chrg_I_1 and/or the second measurement value AD_Chrg_I_2 are/is faulty based on a permissible range obtained by adding the second permissible range to the first permissible range.

In S580, the second MPU 60 determines whether the value of the measurement error counter Cerr_I_3 is smaller than a third counter threshold Cth3 that is preset.

If determining that the value of the measurement error counter Cerr_I_3 is smaller than the third counter threshold Cth3 (S580: YES), then the second MPU 60 determines that the measurement circuit is in a proper state and then ends the present process.

If determining that the value of the measurement error counter Cerr_I_3 is greater than or equal to the third counter threshold Cth3 (S580: NO), then the second MPU 60 proceeds to a process of S590.

In S590, the second MPU 60 detects that the measurement circuit is in the fault condition and then turns on the fault flag to end the present process.

The third counter threshold Cth3 is set to, for example, the same value of “32” as the first and second count thresholds Cth1, Cth2 in the example embodiment above.

The second modified embodiment exhibits effects to be described below.

The fault condition of the measurement circuit can be detected with satisfactory accuracy based on the third difference Diff_I_3 between the first and second measurement values AD_Chrg_I_1, AD_Chrg_I_2.

### Other Embodiments

(a) In the example embodiment above, the second MPU 60 calculates the first and second differences Diff_I_1, Diff_I_2 in the process of S340. However, these differences may not necessarily be calculated. That is, the second MPU 60 may skip the process of S340. In this case, the second MPU 60 can determine whether the first measurement value AD_Chrg_I_1 is within the first permissible range in S350. The first permissible range ranges from a value obtained by deducting the first threshold value Dth1 from the desired value PWM_SET to a value obtained by adding the first threshold value to the desired value PWM_SET. Furthermore, the second MPU 60 can determine whether the second measurement value AD_Chrg_I_2 is within the second permissible range in S380. The second permissible range ranges from a value obtained by deducting the second threshold Dth2 from the desired value PWM_SET to a value obtained by adding the second threshold value Dth2 to the desired value PWM_SET.

(b) In the example embodiment above, the battery charger 40 includes one second attachment portion 44 to attach the battery pack 2 thereto. However, the battery charger 40 may include two or more second attachment portions 44.

In this case, there may be provided two or more second power-supply circuits 50, two or more charge current paths 48, and the like to one battery charger 40 so that the one battery charger 40 can individually charge batteries 10 inside battery packs 2 attached to the two or more second attachment portions 44. In this case, the one battery charger 40 can include first and second amplifiers for each of the two or more charge current paths 48.

(c) Two or more functions performed by a single element in the above-described embodiments may be achieved by two or more elements, or a function performed by a single element may be achieved by two or more elements. Furthermore, two or more functions performed by two or more elements may be achieved by a single element, and a function performed by two or more elements may be achieved by a single element. Furthermore, a part of a configuration in the above-described embodiments may be omitted. Still further, at least a part of a configuration in the above-described embodiments may be added to, or may replace, another configuration in the above-described embodiments. Any and all modes encompassed by the technical ideas specified by the languages in the claims are embodiments of the present disclosure.

(d) The battery charger in the present disclosure can be configured as a device to detect a charge current. Furthermore, the battery charger in the present disclosure may also be practiced in various forms, such as a charging system, a program for a computer to function as the battery charger, a non-transitory tangible storage medium, such as a semiconductor memory, in which this program is stored, or a method of determining a fault in battery charge.

What is claimed is:

1. A battery charger comprising:
a terminal configured to be electrically connected to a battery;
a power-supply circuit configured to generate a charge current;
a charge current path configured to deliver the charge current between the power-supply circuit and the terminal;
a measurement circuit including:
a voltage generator (i) on the charge current path and (ii) configured to receive the charge current to thereby generate one or more voltages, the one or more voltages corresponding to a magnitude of the charge current flowing through the charge current path; and
an amplifier circuit configured to amplify the one or more voltages to thereby output at least a first amplified voltage and a second amplified voltage; and
a control circuit configured to:
cyclically obtain at least the first amplified voltage and the second amplified voltage; and
detect that the measurement circuit is in a fault condition based on at least the first amplified voltage and the second amplified voltage obtained.

2. The battery charger according to claim 1,
wherein the voltage generator has a single shunt resistor (i) having a first end and a second end and (ii) being on the charge current path so as to receive the charge current, and
wherein the one or more voltages include a voltage between the first end and the second end.

3. The battery charger according to claim 1, wherein the voltage generator includes:
a first shunt resistor (i) having a first end and a second end and (ii) being on the charge current path so as to receive the charge current; and
a second shunt resistor (i) having a third end and a fourth end and (ii) connected to the first shunt resistor in series so as to receive the charge current,
wherein the one or more voltages include (i) a first voltage between the first end and the second end of the first shunt resistor and (ii) a second voltage between the third end and the fourth end of the second shunt resistor, and
wherein the amplifier circuit is configured to (i) amplify the first voltage to thereby generate and output the first amplified voltage and (ii) amplify the second voltage to thereby generate and output the second amplified voltage.

4. The battery charger according to claim 3, wherein the amplifier circuit includes:
a first amplifier configured to amplify the first voltage to thereby generate and output the first amplified voltage, and
a second amplifier (i) being an electronic component independent from the first amplifier and (ii) configured to amplify the second voltage to thereby generate and output the second amplified voltage.

5. The battery charger according to claim 1,
wherein the control circuit is configured to detect that the measurement circuit is in the fault condition based on the first amplified voltage being out of a preset first permissible range and/or the second amplified voltage being out of a preset second permissible range.

6. The battery charger according to claim 5, wherein the control circuit is configured to:
calculate a first difference between the first amplified voltage and a desired voltage, the desired voltage corresponding to a desired value of the charge current;
calculate a second difference between the second amplified voltage and the desired voltage; and
detect that the measurement circuit is in the fault condition based on the first difference being out of a preset third permissible range and/or the second difference being out of a preset fourth permissible range.

7. The battery charger according to claim 5, wherein the control circuit is configured to:
calculate a third difference between the first amplified voltage and the second amplified voltage; and
detect that the measurement circuit is in the fault condition based on the third difference being out of a preset fifth permissible range.

8. The battery charger according to claim 1, wherein the control circuit is configured to, during the battery charger charging the battery, control the power-supply circuit to stop supply of the charge current therefrom based on the control circuit detecting that the measurement circuit is in the fault condition.

9. The battery charger according to claim 1,
wherein the one or more voltages include a first voltage,
wherein the amplifier circuit includes:
a first amplifier configured to amplify the first voltage at a first accuracy; and
a second amplifier configured to amplify the first voltage at a second accuracy, the second accuracy being distinctive from the first accuracy.

10. The battery charger according to claim 1,
wherein the one or more voltages include a first voltage and a second voltage, the second voltage being distinctive from the first voltage,
wherein the amplifier circuit includes:
a first amplifier configured to amplify the first voltage at a first accuracy; and
a second amplifier configured to amplify the second voltage at a second accuracy, the second accuracy being distinctive from the first accuracy.

11. The battery charger according to claim 9, further comprising a feedback circuit connected to the first amplifier and to the power-supply circuit,
wherein the first accuracy is higher than the second accuracy,
wherein the first amplifier is configured to input the first amplified voltage to the feedback circuit, and
wherein the feedback circuit is configured to control the power-supply circuit so as to maintain the first amplified voltage at a desired voltage, the desired voltage corresponding to a desired value of the charge current.

12. The battery charger according to claim 10, further comprising a feedback circuit connected to the first amplifier and to the power-supply circuit,
wherein the first accuracy is higher than the second accuracy,
wherein the first amplifier is configured to input the first amplified voltage to the feedback circuit, and
wherein the feedback circuit is configured to control the power-supply circuit so as to maintain the first amplified voltage at a desired voltage, the desired voltage corresponding to a desired value of the charge current.

13. The battery charger according to claim 9,
wherein the first amplifier includes a first differential amplifier having a first offset voltage,
wherein the second amplifier includes a second differential amplifier having a second offset voltage, and
wherein the first offset voltage is lower than the second offset voltage.

14. The battery charger according to claim 10, wherein the first amplifier includes a first differential amplifier having a first offset voltage,
wherein the second amplifier includes a second differential amplifier having a second offset voltage, and
wherein the first offset voltage is lower than the second offset voltage.

15. A method for detecting a measurement circuit of a battery charger being in a fault condition, the method comprising:
generating one or more voltages in the measurement circuit based on a magnitude of a charge current, the measurement circuit including an amplifier circuit;
amplifying the one or more voltages with the amplifier circuit to thereby generate at least a first amplified voltage and a second amplified voltage, and
detecting the measurement circuit being in the fault condition based on at least the first amplified voltage and the second amplified voltage.
